(19) United States
(12) Patent Application Publication
(10) Pub. No.: US 2007/0000125 A1
(43) Pub. Date: Jan. 4, 2007

(54) Component mounting device and component mounting method

(76) Inventor: Atsuhiko Hirata, Yasu-shi (JP)

Correspondence Address: OSTROLENK FABER GERB & SOFFEN, 1180 AVENUE OF THE AMERICAS, NEW YORK, NY, 100368403, US

(21) Appl. No.: 10/568,908

(22) PCT Filed: Aug. 2, 2004
(86) PCT No.: PCT/JP04/11049

§ 371 Date: Jul. 24, 2006

(30) Foreign Application Priority Data
Aug. 20, 2003 (JP) 2003296089

(51) Int. Cl. H05K 3/00

(52) U.S. Cl. 29/829

(57) ABSTRACT

A component mounting device includes a head to which a component is attached e.g. by suction and a base for holding a substrate onto which the component is to be mounted. The head and the base are shifted relatively in an axial direction in order to mount the component onto the substrate. An attachment part is detachably attached to at least one of the head and the base, and has a projection at a position distant from the center of axis. The head and the base are shifted relatively in the axial direction so that the projection comes into contact with an opposing section on the head or the base. The relative shifting of the head and the base is repeated for a plurality of cycles while changing the attachment orientation of the attachment part for every cycle so that a plurality of coordinate values is obtained, each coordinate value corresponding to a contact point between the projection and the opposing section in the axial direction. A correcting mechanism included in the device adjusts a relative angle between the head and the base on the basis of the obtained coordinate values.

### CROSS-REFERENCE TO RELATED APPLICATION

The present application is a 35 U.S.C. §371 national phase conversion of PCT/JP2004/011049 filed Aug. 2, 2004, which claims priority of Japanese application no. 2003-296089 filed Aug. 20, 2003, which are incorporated herein in their entirety.

### BACKGROUND OF THE INVENTION

1. Field of the Invention

The present invention relates to a mounting device and a mounting method in which, for example, an electronic component held by a mounting head is mounted on a substrate held by a base. In particular, the present invention relates to a method for adjusting a relative angle between the head and the base.

2. Background Art

In a component mounting device having a mounting head and a base for holding a substrate, a component is held on the head by suction, and the base holds a substrate onto which the component is to be mounted. The head and the base are shifted relatively in an axial direction in order to pressure-mount the component onto the substrate. In such a device, the relative angle between the head and the base must be adjusted with high precision.

Three documents of background interest are as follows:
Patent Document 1: Japanese Unexamined Patent Application Publication No. 5-218140
Patent Document 2: Japanese Unexamined Patent Application Publication No. 6-140467
Patent Document 3: Japanese Unexamined Patent Application Publication No. 10-150296

In one example of an adjustment unit for adjusting the relative angle between the head and the base, semiconductor pressure sensors are provided at four corners of the base for detecting the degree of parallelism between a pressing face of the head and a receiving face of the base. Based on the detected values, the tilt of the head is corrected (for example, see Patent Document 1).

In another example of an adjustment unit, four corners of the base are provided with capacitors and capacitance detectors. The tilt angle of the head with respect to the base is determined from the detected capacitance values. Based on the tilt angle, the tilt of the head is corrected (for example, see Patent Document 2).

In a further example of an adjustment unit, the base is provided with three piezoelectric elements. The tilt angle of the head with respect to the base is determined from signals received from the piezoelectric elements. The tilt of the head is corrected based on the determined tilt angle (for example, see Patent Document 3).

The conventional examples of adjustment units described above are each provided with a plurality of detectors, such that the degree of parallelism is detected based on the difference in the detected values. In addition to requiring a plurality of detectors, such conventional adjustment units are problematic in having variations in the detectors and requiring correcting means for ensuring that the detectors have uniform characteristics.

### SUMMARY OF THE INVENTION

The present invention provides a component mounting device and a component mounting method that do not require a plurality of detectors so as to prevent variations in the detectors and to eliminate the need for providing correcting means for making the detector characteristics uniform.

An embodiment of the present invention provides a component mounting device, which includes a head to which a component is attached by suction; and a base for holding a substrate onto which the component is to be mounted. The head and the base are shifted relatively in an axial direction in order to mount the component attached to the head onto the substrate held by the base. The component mounting device includes a correcting mechanism that adjusts a relative angle between the head and the base. An attachment part is detachably attached to at least one of the head and the base, and has a projection at a position distant from the center of axis. The head and the base are shifted relatively in the axial direction so that the projection comes into contact with an opposing section on the head or the base. The relative shifting of the head and the base is repeated for a plurality of cycles while changing the attachment orientation of the attachment part for every cycle so that a plurality of coordinate values is obtained, each coordinate value corresponding to a contact point between the projection and the opposing section in the axial direction. The correcting mechanism adjusts the relative angle between the head and the base on the basis of the obtained coordinate values.

According to another aspect of the present invention, the plurality of cycles may include at least three cycles such that the plurality of coordinate values obtained by the correcting mechanism includes at least three coordinate values.

A further aspect of the present invention provides a component mounting device, which includes a head to which a component is attached by suction; and a base for holding a substrate onto which the component is to be mounted. The head and the base are shifted relatively in an axial direction in order to mount the component attached to the head onto the substrate held by the base. The component mounting device includes a correcting mechanism that adjusts a relative angle between the head and the base. An attachment part is detachably attached to at least one of the head and the base, and has a projection at a position distant from the center of axis. The head and the base are shifted relatively in the axial direction so that the projection comes into contact with an opposing section on the head or the base. A first coordinate value in the axial direction is obtained, the first coordinate value corresponding to a contact point between the projection and the opposing section. The attachment orientation of the attachment part is then changed so that the projection comes into contact with another opposing section on the head or the base. A second coordinate value in the axial direction is obtained, the second coordinate value corresponding to a contact point between the projection and the other opposing section. The correcting mechanism adjusts the relative angle between the head and the base while maintaining the contact state between the projection and the other opposing section in a manner such that the second coordinate value is equal to a predetermined coordinate value determined on the basis of the first coordinate value.

According to another aspect of the present invention, the process for obtaining the first coordinate value may be performed two or more times.

According to yet another aspect of the present invention, the component mounting device may further include a load-detecting mechanism for detecting a contact load between the head and the base. The correcting mechanism may allow the projection to come into contact with the corresponding opposing section such that a load value detected by the load-detecting mechanism is equal to a predetermined load value.

Another embodiment of the present invention provides a method for mounting a component attached to a head by suction onto a substrate held by a base, by shifting the head and the base relatively in an axial direction. The method includes the steps of attaching an attachment part to at least one of the head and the base in a detachable fashion, the attachment part having a projection at a position distant from the center of axis; shifting the head and the base relatively in the axial direction so that the projection comes into contact with an opposing section on the head or the base, the relative shifting of the head and the base being repeated for a plurality of cycles while changing the attachment orientation of the attachment part for every cycle so that a plurality of coordinate values is obtained, each coordinate value corresponding to a contact point between the projection and the opposing section in the axial direction; and adjusting a relative angle between the head and the base on the basis of the obtained coordinate values.

According to an aspect of the present invention, the plurality of cycles may include at least three cycles such that the plurality of coordinate values includes at least three coordinate values.

Yet another embodiment of the present invention provides a method for mounting a component attached to a head by suction onto a substrate held by a base, by shifting the head and the base relatively in an axial direction. The method includes the steps of attaching an attachment part to at least one of the head and the base in a detachable fashion, the attachment part having a projection at a position distant from the center of axis; shifting the head and the base relatively in the axial direction so that the projection comes into contact with an opposing section on the head or the base; obtaining a first coordinate value in the axial direction, the first coordinate value corresponding to a contact point between the projection and the opposing section; changing the attachment orientation of the attachment part so that the projection comes into contact with another opposing section on the head or the base; obtaining a second coordinate value in the axial direction, the second coordinate value corresponding to a contact point between the projection and said other opposing section; and adjusting a relative angle between the head and the base while maintaining the contact state between the projection and said other opposing section in such a manner that the second coordinate value is equal to a predetermined coordinate value determined on the basis of the first coordinate value.

According to an aspect of the present invention, the process for obtaining the first coordinate value may be performed two or more times.

According to another aspect of the present invention, the method may further include a detecting step for detecting a contact load value between the head and the base. In this case, the projection comes into contact with the corresponding opposing section such that the detected contact load value is equal to a predetermined load value.

According to the foregoing embodiments of the present invention, the head and the base are shifted relatively in the axial direction so that the projection of the attachment part comes into contact with an opposing section on the head or the base. The relative shifting of the head and the base is repeated for a plurality of cycles while changing the attachment orientation of the attachment part for every cycle, so that a plurality of coordinate values in the axial direction is obtained. The relative angle between the head and the base is adjusted on the basis of the obtained coordinate values. Consequently, only a single detector is sufficient for determining the coordinate values in the axial direction. Thus, the problems related with variations in detectors and the need for providing correcting means for making the detector characteristics uniform are solved. Accordingly, the parallelism between the head and the base can be attained with a simple structure.

Since a linear scale unit is used for the z axis of the component mounting device, as long as the base is provided with an angle adjustment mechanism, such as a commercially-available goniometer base, a tilt-adjustment process can be readily implemented simply by adding a tilt-adjustment attachment part, as described above. Accordingly, the parallelism between the head and the base can be attained.

Further, since the plurality of cycles may include at least three cycles such that the plurality of coordinate values includes at least three coordinate values, the relative angle between the head and the base can be determined with high accuracy.

Moreover, the head and the base are shifted relatively in the axial direction so that the projection of the attachment part comes into contact with an opposing section on the head or the base. The first coordinate value in the axial direction is then obtained. Subsequently, the attachment orientation of the attachment part is changed so that the projection comes into contact with another opposing section on the head or the base. Then the second coordinate value in the axial direction is obtained. The relative angle between the head and the base is adjusted while maintaining the contact state between the projection and the opposing section in such a manner that the second coordinate value is equal to a predetermined coordinate value determined on the basis of the first coordinate value. Accordingly, the relative angle between the head and the base can be adjusted within a short period of time.

According to a further aspect of the present invention, since the process for obtaining the first coordinate value may be performed two or more times, the relative angle between the head and the base can be adjusted with higher precision.

According to yet another aspect of the present invention, since the projection coming into contact with the corresponding opposing section may be controlled such that the contact load value between the head and the base is equal to a predetermined load value, the detection accuracy of each coordinate value and the parallelism between the head and the base is further enhanced.

Other features and advantages of the present invention will become apparent from the following description of embodiments of the invention which refers to the accompanying drawings.

### BRIEF DESCRIPTION OF THE DRAWINGS

FIG. 1 is a front view of a component mounting device according to an embodiment of the invention.

FIG. 2 is a perspective view showing a joining section of the embodiment during a tilt-adjustment process.

FIG. 3 is a perspective view showing the joining section during a normal operation.

FIG. 4 is a perspective view of a substrate attachment part.

FIG. 5 is a perspective view of a workpiece attachment part.

FIG. 6 is a perspective view of a tilt-adjustment attachment part.

FIG. 7 is a plan view of the tilt-adjustment attachment part.

FIG. 8 is a plan view of the substrate attachment part.

### DETAILED DESCRIPTION OF AN EMBODIMENT OF THE INVENTION

An embodiment of the present invention will now be described with reference to the drawings.

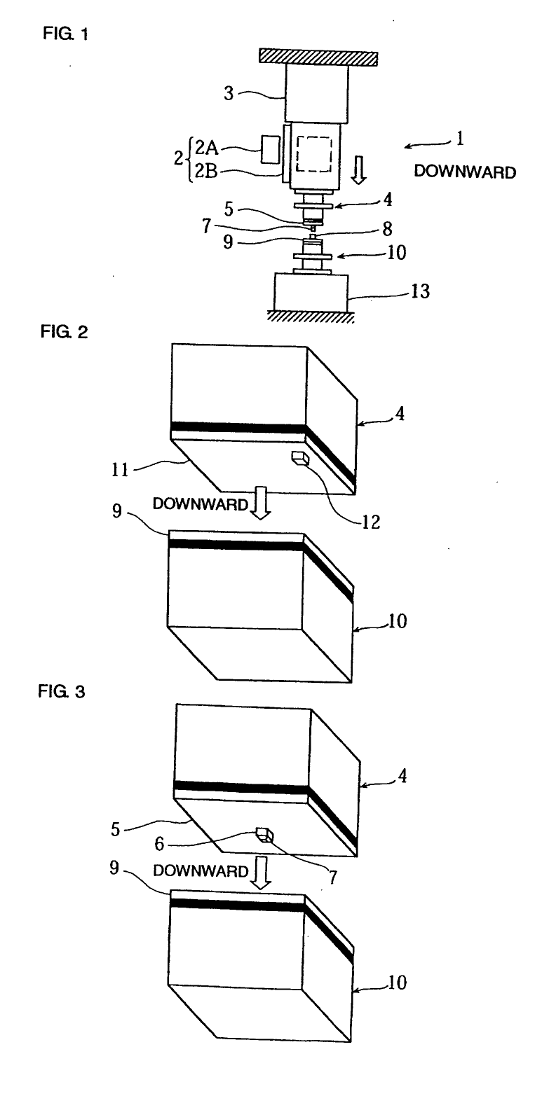

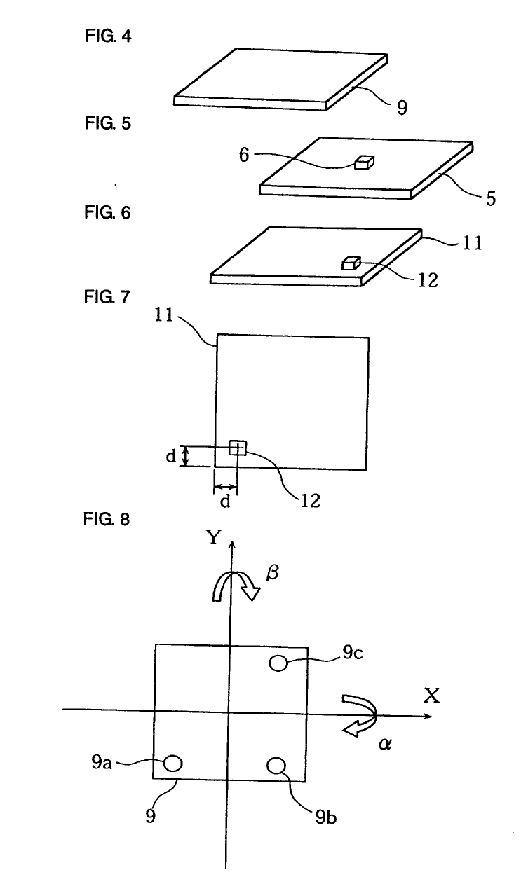

FIGS. 1 to 8 illustrate a component mounting device and a component mounting method according to an embodiment of the present invention. In the drawings, reference numeral 1 indicates a component mounting device, which mainly includes a head 4 and a base 10. The head 4 has a workpiece attachment part 5 to which a component 7 is held by suction. On the other hand, the base 10 has a substrate attachment part 9 for holding a substrate 8. The component 7 is pressure-mounted to the substrate 8 disposed on the substrate attachment part 9.

The head 4 holds the workpiece attachment part 5 in a replaceable fashion by suction, and is driven upward and downward in an axial direction (i.e. in the vertical direction in FIG. 1) by a driving mechanism 3. The driving mechanism 3 includes a linear scale unit 2 for position detection and a load-detecting unit (shown schematically in FIG. 1). The driving mechanism 3 accurately controls the axial positioning of the head 4 and also controls the load when the workpiece 7 is in contact with the substrate 8. The linear scale unit 2 includes a reading head 2A attached to a stationary portion of the device 1 and a scale 2B attached to the head 4.

A projection 6 is provided in the center of a front face of the workpiece attachment part 5. The projection 6 holds the workpiece 7 by suction. While the workpiece 7 is held by the projection 6, the driving mechanism 3 drives the head 4 downward so that the workpiece 7 is pressure-mounted to the substrate 8.

On the other hand, the base 10 holds the substrate attachment part 9 in a replaceable fashion by suction. The substrate 8 is supported on a front face of the substrate attachment part 9 by suction. The angle of the front face of the substrate attachment part 9 (i.e. the tilt angle of the substrate attachment part 9 with respect to the axial direction) is freely adjustable with an angle adjustment mechanism 13.

In the component mounting device 1 according to this embodiment for mounting the workpiece 7 to the substrate 8, the degree of parallelism between the workpiece suction surface and the substrate suction surface must be high in order to mount the workpiece 7 to the substrate 8 with high precision. Accordingly, a mechanism is provided for correcting an assembly error that may impair the parallelism between the head 4 and the base 10.

This embodiment applies a configuration and a process described below for the error correction.

In place of the workpiece attachment part 5, a tilt-adjustment attachment part 11 is first attached to the head 4 by suction. Although the workpiece attachment part 5 and the tilt-adjustment attachment part 11 are both defined by a flat rectangular plate having a rectangular projection on a surface thereof, the workpiece attachment part 5 has the projection 6 in the center thereof, whereas the tilt-adjustment attachment part has a projection 12 disposed near one corner thereof.

An assembly error is corrected in accordance with a procedure described below. The substrate attachment part 9 is preliminarily held by the base 10 by suction. By lowering the head 4, the projection 12 of the tilt-adjustment attachment part 11 comes into contact with the front face of the substrate attachment part 9. The head 4 is lowered until the contact load reaches a predetermined value. The linear scale unit 2 then reads a coordinate of the contact point, and stores the read coordinate as a first coordinate value.

Then, the head 4 is lifted, and the tilt-adjustment attachment part 11 is removed from the head 4. The tilt-adjustment attachment part 11 is turned around by 90°, and is attached onto the head 4 again by suction. The head 4 is then lowered so that the projection 12 of the tilt-adjustment attachment part 11 comes into contact with the front face of the substrate attachment part 9. Similarly, the head 4 is lowered until the contact load reaches the predetermined value. The linear scale unit 2 then reads a coordinate of the contact point, and stores the read coordinate as a second coordinate value.

This process is repeated while turning the tilt-adjustment attachment part 11 around by 90° each time in order to determine a relative (tilt) angle between the head 4 and the front face of the substrate attachment part 9.

On the other hand, the angle adjustment mechanism 13 is disposed below the base 10 and is provided for freely adjusting the angle of the base 10, or more specifically, the angle of the front face of the substrate attachment part 9. The tilt angle is calculated on the basis of the first, second, third and fourth coordinate values obtained from the above process. Thus, the angle adjustment mechanism 13 is adjusted to an appropriate angle so that the suction surface of the head 4 and the front face of the substrate attachment part 9 become parallel to each other.

Next, the tilt-adjustment attachment part 11 is removed from the head 4 and replaced with the workpiece attachment part 5. Since the back face of the workpiece attachment part 5 and the projection 6 serving as the workpiece suction surface are processed to have a high degree of parallelism, the workpiece suction surface of the workpiece attachment part 5 and the substrate suction surface of the substrate attachment part 9 are therefore parallel to each other.

If the error affecting the parallelism is relatively small, an approximate and simple tilt-adjustment process is preferably performed. Such a simple adjustment process can be achieved in accordance with an operation described below.

This simple tilt-adjustment process is based on the following conditions: the tilt-adjustment attachment part 11 is square-shaped and has the projection 12 on a diagonal line as shown in FIG. 7; and the substrate attachment part 9 is a flat square plate having the same dimension as the tilt-adjustment attachment part 11. Rotational axes (x axis, y axis) of the angle adjustment mechanism 13 are assumed to be disposed at substantially the same height as the substrate attachment part 9. That is, the angle adjustment mechanism 13, which may be a commercially-available goniometer base, causes the substrate attachment part 9 to rotate (tilt) about these axes. Moreover, each rotational axis is assumed to be substantially parallel to the opposing edges of the substrate attachment part 9 and to extend through the center of the front face of the substrate attachment part 9.

First, the tilt-adjustment attachment part 11 is attached onto the head 4 by suction in such a manner that the projection 12 is contactable with the substrate attachment part 9 at a position 9a shown in FIG. 8. The head 4 is then lowered so that the projection 12 comes into contact with the substrate attachment part 9. The contact load is controlled, and a coordinate value of the contact point is obtained. The coordinate value in this case will be defined as Z1.

Then, the head 4 is lifted. The tilt-adjustment attachment part 11 is then removed from the head 4, and is turned around by 90°. The tilt-adjustment attachment part 11 is attached onto the head 4 by suction in such a manner that the projection 12 is contactable with the substrate attachment part 9 at a position 9b in FIG. 8. The head 4 is lowered so that the projection 12 comes into contact with the substrate attachment part 9. The contact load is controlled, and a coordinate value of the contact point is obtained. The coordinate value in this case will be defined as Z2.

While maintaining the contact state between the projection 12 and the substrate attachment part 9 at the position 9b and controlling the contact load, a rotational angle β of the angle adjustment mechanism 13 about the y axis is adjusted so that the coordinate read by the linear scale unit 2 is equal to (Z1+Z2)/2. Accordingly, the angle adjustment about the y axis is completed.

Next, the head 4 is lifted. The tilt-adjustment attachment part 11 is then removed from the head 4, and is turned around by 90°. The tilt-adjustment attachment part 11 is attached onto the head 4 by suction in such a manner that the projection 12 is contactable with the substrate attachment part 9 at a position 9c in FIG. 8. The head 4 is lowered so that the projection 12 comes into contact with the substrate attachment part 9. The contact load is controlled, and a coordinate value of the contact point is obtained. The coordinate value in this case will be defined as Z3.

While maintaining the contact state between the projection 12 and the substrate attachment part 9 at the position 9c and controlling the contact load, a rotational angle α of the angle adjustment mechanism 13 about the x axis is adjusted so that the coordinate read by the linear scale unit 2 is equal to ((Z1+Z2)/2+Z3)/2. Accordingly, the angle adjustment about the x axis is completed. The head 4 is then lifted, and the tilt-adjustment attachment part 11 is removed from the head 4. Finally, the workpiece attachment part 5 is attached to the head 4, whereby the adjustment process is completed.

As described above, in the component mounting device and the component mounting method according to the above embodiments of the present invention, the head 4 is lowered so as to allow the projection 12 of the tilt-adjustment attachment part 11 to come into contact with the front face of the substrate attachment part 9 with a predetermined contact load. The linear scale unit 2 then reads a coordinate of the contact point. This operation is repeated for multiple cycles while changing the attachment orientation of the tilt-adjustment attachment part for each cycle. The tilt relationship between the head 4 and the base 10 is determined on the basis of the coordinate values that are read. Therefore, the present invention does not require multiple detectors, such as pressure sensors, which implies that variation and characteristic adjustments between detectors are not necessary. Accordingly, the degree of parallelism between the head and the base can be determined with a simple structure, with a simple operation, and at a low cost, whereby the head and the base can be made parallel to each other.

Since a linear scale unit is used in the component mounting device 1, as long as the base is provided with an angle adjustment mechanism, such as a commercially-available goniometer base, the tilt-adjustment process can be readily implemented simply by adding the tilt-adjustment attachment part.

Furthermore, although the above embodiments are directed to a type of mounting device that pressure-mounts a component to a substrate, the present invention is also applicable to a type for simply mounting or bonding a component to a substrate.

Although the present invention has been described in relation to particular embodiments thereof, many other variations and modifications and other uses will become apparent to those skilled in the art. Therefore, the present invention is not limited by the specific disclosure herein.

What is claimed is:

1. A component mounting device including a head for holding a component to be mounted on a substrate; and a base for holding a substrate onto which the component is to be mounted, the head and the base being shiftable relatively in an axial direction in order to mount the component held by the head onto the substrate held by the base,
wherein the component mounting device comprises a correcting mechanism that adjusts a relative angle between the head and the base,
wherein an attachment part is detachably attached to at least one of the head and the base, the attachment part having a projection at a position distant from the center of the attachment part, wherein the head and the base are shifted relatively in the axial direction so that the projection comes into contact with an opposing section on the head or the base, wherein the relative shifting of the head and the base is repeated for a plurality of cycles while changing the attachment orientation of the attachment part for every cycle so that a plurality of coordinate values is obtained, each coordinate value corresponding to a contact point between the projection and the opposing section in the axial direction, and wherein the correcting mechanism adjusts the relative angle between the head and the base on the basis of the obtained coordinate values.

2. The component mounting device according to claim 1, wherein the plurality of cycles includes at least three cycles such that the plurality of coordinate values obtained by the correcting mechanism includes at least three coordinate values.

3. A component mounting device including a head for holding a component is to be mounted on a substrate; and a base for holding a substrate onto which the component is to be mounted, the head and the base being shiftable relatively in an axial direction in order to mount the component attached to the head onto the substrate held by the base,
wherein the component mounting device comprises a correcting mechanism that adjusts a relative angle between the head and the base,
wherein an attachment part is detachably attached to at least one of the head and the base, the attachment part having a projection at a position distant from the center of the attachment part, wherein the head and the base are shifted relatively in the axial direction so that the projection comes into contact with an opposing section on the head or the base, wherein a first coordinate value in the axial direction is obtained, the first coordinate value corresponding to a contact point between the projection and the opposing section, wherein the attachment orientation of the attachment part is changed so that the projection comes into contact with another opposing section on the head or the base, wherein a second coordinate value in the axial direction is obtained, the second coordinate value corresponding to a contact point between the projection and said another opposing section, and wherein the correcting mechanism adjusts the relative angle between the head and the base while maintaining the contact state between the projection and said another opposing section in a manner such that the second coordinate value is equal to a predetermined coordinate value determined on the basis of the first coordinate value.

4. The component mounting device according to claim 3, wherein the process for obtaining the first coordinate value is performed two or more times.

5. The component mounting device according to any one of claims 1 to 4, further comprising a load-detecting mechanism for detecting a contact load between the head and the base,
wherein the correcting mechanism allows the projection to come into contact with the corresponding opposing section such that a detected load value by the load-detecting mechanism is equal to a predetermined load value.

6. A method for mounting a component attached to a head onto a substrate held by a base by shifting the head and the base relatively in an axial direction, the method comprising the steps of:
attaching an attachment part to at least one of the head and the base in a detachable fashion, the attachment part having a projection at a position distant from the center of axis;
shifting the head and the base relatively in the axial direction so that the projection comes into contact with an opposing section on the head or the base, the relative shifting of the head and the base being repeated for a plurality of cycles while changing the attachment orientation of the attachment part for every cycle so that a plurality of coordinate values is obtained, each coordinate value corresponding to a contact point between the projection and the opposing section in the axial direction; and
adjusting a relative angle between the head and the base on the basis of the obtained coordinate values.

7. The method according to claim 6, wherein the plurality of cycles includes at least three cycles such that the plurality of coordinate values includes at least three coordinate values.

8. A method for mounting a component attached to a head onto a substrate held by a base by shifting the head and the base relatively in an axial direction, the method comprising the steps of:
attaching an attachment part to at least one of the head and the base in a detachable fashion, the attachment part having a projection at a position distant from the center of axis;
shifting the head and the base relatively in the axial direction so that the projection comes into contact with an opposing section on the head or the base;
obtaining a first coordinate value in the axial direction, the first coordinate value corresponding to a contact point between the projection and the opposing section;
changing the attachment orientation of the attachment part so that the projection comes into contact with another opposing section on the head or the base;
obtaining a second coordinate value in the axial direction, the second coordinate value corresponding to a contact point between the projection and said another opposing section; and
adjusting a relative angle between the head and the base while maintaining the contact state between the projection and said another opposing section in a manner such that the second coordinate value is equal to a predetermined coordinate value determined on the basis of the first coordinate value.

9. The method according to claim 8, wherein the process for obtaining the first coordinate value is performed two or more times.

10. The method according to any one of claims 6 to 9, further comprising a detecting step of detecting a contact load value between the head and the base,
wherein the projection is brought into contact with the corresponding opposing section such that the detected contact load value is equal to a predetermined load value.
